(19) United States
(12) Patent Application Publication
(10) Pub. No.: US 2009/0046437 A1
(43) Pub. Date: Feb. 19, 2009

(54) EXPANSION CARD AND FIXING STRUCTURE FOR EXPANSION CARD

(75) Inventors: Chi-Kang Hsieh, Taipei City (TW); Tzu-Wen Sung, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 11/840,702

(22) Filed: Aug. 17, 2007

(51) Int. Cl. H01R 12/18; H05K 1/00

(52) U.S. Cl. 361/752; 439/65

(57) ABSTRACT

An expansion card capable of installing a module on a mainboard is provided. The expansion card includes a first circuit board for the module to be installed on, a second circuit board inserted to the mainboard, a flexible board electrically connecting the first circuit board and the second circuit board, and a fixing element fastened on the junction where the flexible board connects the first circuit board and the second circuit board.

### BACKGROUND OF THE INVENTION

1. Field of the Invention

The present invention generally relates to a computer peripheral electronic device, and more particularly, to an expansion card and a fixing structure for the expansion card.

2. Description of Related Art

With the rapid development of the semiconductor industry, the design of electronic devices aim toward miniaturization and multi-functionalism. However, because of low cost, high flexibility and expandability of desktop computers, desktop computers still play an important role in various markets, such as servers.

When a user needs to expand the function of a desktop computer, expansion cards with for example a PCI or AGP interface are often used. However, in a server with a relatively high electronic device density, there may not be sufficient space. Consequently, an expansion card for adapting for example hard disks, usually has a circuit board that is divided into two parts, and the two parts are connected by a flexible board to increase flexibility of disposition of the expansion card.

FIG. 1 is a three-dimensional view of a conventional hard disk expansion card. As shown in FIG. 1, the conventional hard disk expansion card 100 has a first circuit board 110, a second circuit board 120, and a flexible board 130 electrically connecting the first circuit board 110 and the second circuit board 120. The first circuit board 110 has a plurality of hard disk connectors 112 thereon, and the second circuit board 120 has a terminal set 122. The hard disk connectors 112 are electrically connected to hard drives (not shown) and the terminal set 122 is inserted into a slot (not shown) on a main board so that the hard drives and the main board are electrically connected.

Although the conventional hard disk expansion card 100 uses the flexible board for electrically connecting the first circuit board 110 and the second circuit board, which resolves the spatial disposition problem, however, the stress resulting from using the hard disk expansion card 100 can easily lead to fractures at the junction between the flexible board 130 and the first circuit board 110 or the second circuit board 120.

For example, to dissemble the hard disk expansion card 100, the user has to apply a definite force to the second circuit board 120 to remove the second circuit board 120 because of the fixing force between the slot and the terminal set 122. However, the stress applied to the second circuit board 120 when removing it from the slot cannot be transmitted to the first circuit board 110 through the flexible board 130. Therefore, relative movement between the first circuit board 110 and the second circuit board 120 is produced and may cause the connecting junction between the flexible board 130 and the first circuit board 110 or the second circuit board 120 to tear.

### SUMMARY OF THE INVENTION

Accordingly, the present invention is directed to an expansion card and a fixing structure for the expansion card capable of preventing lacerate of a flexible board due to stress.

The present invention provides an expansion card capable of installing a module on a main board. The expansion card includes a first circuit board for the module to be installed on, a second circuit board inserted to the main board, a flexible board electrically connecting the first circuit board and the second circuit board, and a fixing element fastened on the junction where the flexible board connects the first circuit board and the second circuit board.

In an embodiment of the present invention, the fixing element has a first plate, at least one reinforcing rib and a second plate, and the reinforcing rib is fastened to the first plate and the second plate.

In an embodiment of the present invention, the fixing element has a first fastening hook and the first circuit board has a first fastening hole. The first fastening hook can be fastened to the first fastening hole.

In an embodiment of the present invention, the fixing element has a second fastening hook and the second circuit board has a second fastening hole. The second fastening hook can be fastened to the second fastening hole.

The present invention also provides an expansion card for installing at least one module to a main board. The expansion card includes a first circuit board, a second circuit board, a flexible board, a fixing element, a first fastening element and a second fastening element. The first circuit board is for the module to be installed on and has at least one first mortise. The second circuit board is inserted onto the main board and has at least one second mortise. The flexible board is electrically connected to the first circuit board and the second circuit board. The fixing element is fastened to the junction where the flexible board connects the first circuit board and the second circuit board. The fixing element has a first fixing hole corresponding to the first mortise, and the fixing element has a second fixing hole corresponding to the second mortise. The first fastening element is fastened to the first mortise and the first fixing hole. The second fastening element is fastened to the second mortise and the second fixing hole.

In an embodiment of the present invention, the first fastening element includes a screw bolt, a rivet, a plastic stud or a tenon.

In an embodiment of the present invention, the second fastening element includes a screw bolt, a rivet, a plastic stud or a tenon.

The present invention also provides a fixing structure for an expansion card used for installing at least one module to a main board. The fixing structure for an expansion card includes a hard disk frame, a first circuit board, a second circuit board, a flexible board and a fixing element. The hard disk frame is disposed on the main board and has at least one compartment for carrying the module. The first circuit board is disposed on the hard disk frame and is for the module to be installed on. The second circuit board is inserted onto the main board. The flexible board is electrically connected to the first circuit board and the second circuit board. The fixing element is fastened on the junction where the flexible board connects the first circuit board and the second circuit board.

In an embodiment of the present invention, the fixing element has a first plate, at least one reinforcing rib and a second plate, and the reinforcing rib is fastened to the first plate and the second plate.

In an embodiment of the present invention, the fixing element has a first fastening hook and the first circuit board has a first fastening groove. The first fastening hook can be fastened to the first fastening groove.

In an embodiment of the present invention, the fixing element has a second fastening hook and the second circuit board has a second fastening groove. The second fastening hook can be fastened to the second fastening groove.

In the present invention, a fixing element is used to connect the junctions where the flexible board connects the first circuit board and the second circuit board. Therefore, relative motion will not occur between the first circuit board and the second circuit board. In other words, the force applied by a user to assemble or dissemble the expansion card of the present invention will not act on the flexible board. As a result, lacerate at the junction between the flexible board and the first circuit board or the second circuit board due to stress can be prevented and thus reliability of the expansion card is increased.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional view of a conventional hard disk expansion card.

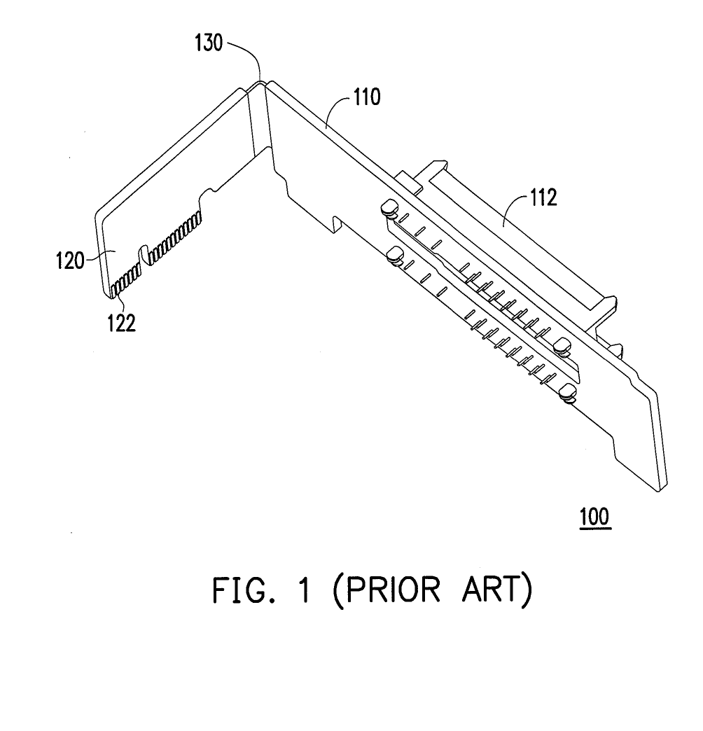

FIG. 2 is a three-dimensional view of a fixing structure for an expansion card according to an embodiment of the present invention.

FIG. 3 is a three-dimensional view of the expansion card in FIG. 2.

FIG. 4 is a three-dimensional view of the fixing element in FIG. 3.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

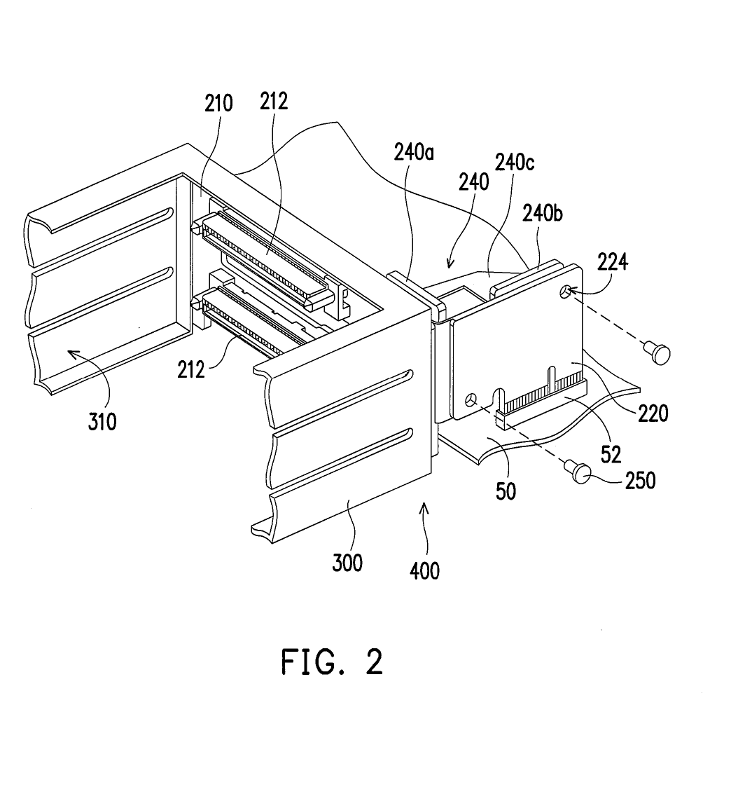

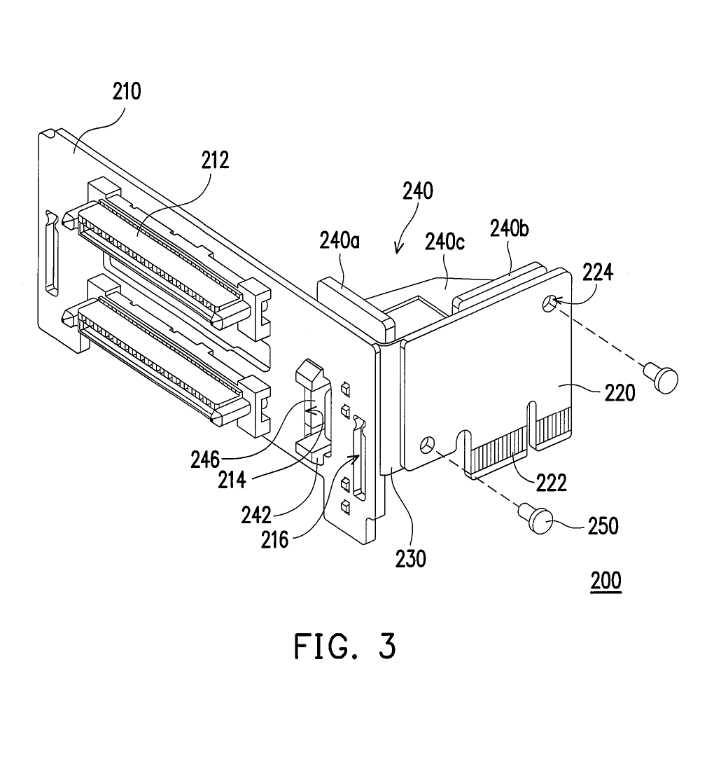

FIG. 2 is a three-dimensional view of a fixing structure for an expansion card according to an embodiment of the present invention. FIG. 3 is a three-dimensional view of the expansion card in FIG. 2. As shown in FIGS. 2 and 3, the expansion card 200 is used for installing at least one module (not shown) to a main board 50. The module is, for example, a hard disk, a compact disk drive, a digital versatile disk drive or a magneto-optical disk drive. In the present embodiment, the expansion card 200 can be combined with a hard disk frame 300 to form a fixing structure 400 for an expansion card. Furthermore, the hard disk frame 300 has an compartment 310 for carrying the hard disk. However, the expansion card 200 can be used alone independent of the hard disk frame 300.

The expansion card includes a first circuit 210, a second circuit 220, a flexible board 230 and a fixing element 240. The first circuit board 210 may have a plurality of electrical connectors 212 for the modules to be installed on so that the first circuit board 210 and the modules are electrically connected. The first circuit board 210 can be disposed on the hard disk frame 300 through a plurality of fixing grooves 216. The first circuit board 210 is electrically connected to the second circuit board 220 through the flexible board 230. The second circuit board 220 can have a terminal set 222 and the main board 50 can have a terminal socket 52. The terminal set 222 can be inserted to the terminal socket 52 so that the second circuit board 220 and the main board 50 are electrically connected, and as a result, the modules and the main board 50 are electrically connected. The fixing element 240 is fastened to junction where the flexible board 230 connects the first circuit board 210 and the second circuit board 220.

Because the expansion card 200 in the present invention has a fixing element 240 fastened to the junction of the first circuit board 210 and the second circuit board 220, force applied to the first circuit board 210 will be transmitted to the second circuit board 220 through the fixing element 240, and force applied to the second circuit board 220 will be transmitted to the first circuit board 210 through the fixing element 240 when the expansion card 220 is assembled or dissembled. In other words, even though the first circuit board 210 or the second circuit board 220 is independently stressed, the first circuit board 210 and the second circuit board 220 will not move relative to each other. Therefore, the junction between the flexible board 230 and the first circuit board 210 or the second circuit board 220 will not be stressed and lacerate at the junction between the flexible board 230 and the first circuit board 210 or the second circuit board 220 can be avoided. Consequently, the reliability of the expansion card 200 is increased.

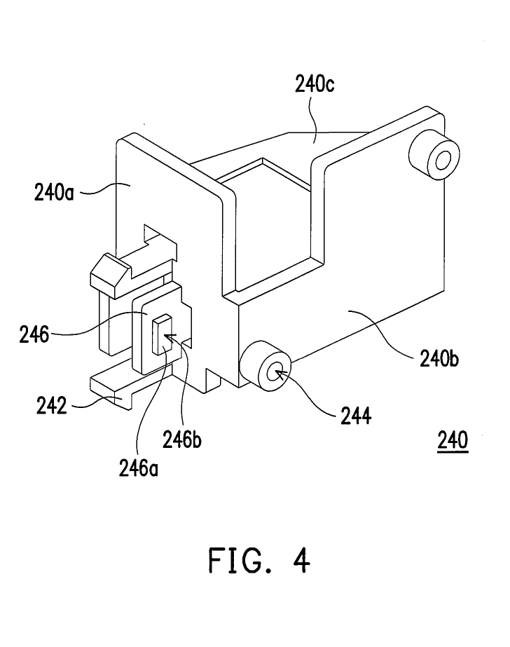

FIG. 4 is a three-dimensional view of the fixing element in FIG. 3. As shown in FIGS. 3 and 4, the fixing element 240 can have a first plate 240a, a second plate 240b and a reinforcing rib 240c fastened to the first plate 240a and the second plate 240b for enhancing the rigidity of the fixing element 240.

In addition, the fixing element 240 may have a plurality of first fastening hooks 242 disposed on the first plate 240a, and the first circuit board 210 may have a first fastening groove 214 disposed thereon. By fastening the first fastening hooks 242 to the first fastening groove 214, the fixing element 240 is fastened on the first circuit board 210. Furthermore, the first fastening hooks 242 may contact, for example, the horizontal edges of the first fastening groove 214. Furthermore, the second circuit board 220 may have a plurality of second mortises 224, and the second plate 240b of the fixing element 240 may have a plurality of second fixing holes 244 disposed corresponding to the second mortises 224. Moreover, the expansion card 200 has a plurality of second fastening elements 250 fastened in the second mortises 224 and the second fixing holes 244 so as to fasten the fixing element 240 on the second circuit board 220. In the present embodiment, the second fastening elements 250 are tenons so as to simplify the process of assembling the fixing element 240 to the second circuit board 220. However, the second fastening elements 250 can be implemented by other means. For example, the second fastening elements 250 can be a screw bolt, a rivet or a plastic stud so that the fixing element 240 is more firmly fastened to the second circuit board 220.

Moreover, the fixing element 240 may have a plurality of supporting elements 246 disposed on the first plate 240a. The supporting elements 246 can be inserted into the first fastening groove 214 such that each supporting elements 246 contacts a vertical edge of the first fastening groove 214. The supporting element 246 may have a bump 246a disposed thereon. The bump 246a has a vertical surface 246b, which can cooperate with the first fastening hooks 242 to fix the fixing element 240 firmly in the first fastening groove 214 in different direction. As a result, the fixing element 240 is appropriately positioned when the fixing element 240 is fastened to the first fastening groove 214 of the first circuit board 210.

Although the first fastening hooks 242, the first fastening groove 214, the second mortises 224, the second fixing holes 244 and the second fastening elements 250 in FIGS. 2, 3 and 4 are used to illustrate the method of fastening the fixing element 240 to the first circuit board 210 and the second circuit board 220, it should be noted that the fixing element 240 can be fastened to the first circuit board 210 and the second circuit board 220 by other means.

For example, in another embodiment (not drawn) of the present invention, the second plate of the fixing element can have a plurality of second fastening hooks and the second circuit board can have a second fastening groove. The second fastening hooks are fastened to the second fastening groove to fasten the fixing element to the second circuit board. In addition, the first circuit board can have a plurality of first mortises, and the first plate of the fixing element can have a plurality of first fixing holes disposed to correspond with the first mortises. Furthermore, the expansion card has a plurality of first fastening elements fastened in the first mortises and the first fixing holes so that the fixing element is fastened to the first circuit board. The method of implementing the second fastening hooks, the second fastening groove, the first mortises, the first fixing holes and the first fastening elements may refer to the method of implementing the first fastening hooks 242, the first fastening groove 214, the second mortise 224, the second fixing holes 244 and the second fastening elements 250 as shown in FIGS. 3 and 4.

Furthermore, the number of first fastening hooks, the first fastening groove, the second fastening hooks, the second fastening groove, the first mortises, the second mortises, the first fixing holes, the second fixing holes, the first fastening elements, the second fastening elements and the reinforcing rib in the foregoing embodiments is not limited. Anyone skill in the art can choose the quantity according to the requirement and, for example, use only one second mortise, one second fixing hole and one second fastening element.

In summary, the expansion card of the present invention has a fixing element fastened to the junction where the flexible board connects the first circuit board and the second circuit board. Therefore, force applied to the first circuit board will be transmitted to the second circuit board through the fixing element, and forces applied to the second circuit board will be transmitted to the first circuit board through the fixing element when the expansion card is assembled or dissembled. In other words, even though the first circuit board or the second circuit board is independently stressed, the first circuit board and the second circuit board will not move relative to each other. As a result, the junction between the flexible board and the first circuit board or the second circuit board will not be stressed and lacerate at the junction between the flexible board and the first circuit board or the second circuit board can be avoided. Consequently, the reliability of the expansion card is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An expansion card for installing at least one module on a main board, the expansion card comprising:
a first circuit board, for the module to be installed on;
a second circuit board, inserted to the main board;
a flexible board, electrically connected to the first circuit board and the second circuit board; and
a fixing element, fastened to a junction where the flexible board connects the first circuit board and the second circuit board.

2. The expansion card according to claim 1, wherein the fixing element has a first plate, at least one reinforcing rib and a second plate, and the reinforcing rib is fastened to the first plate and the second plate.

3. The expansion card according to claim 1, wherein the fixing element has a first fastening hook and the first circuit board has a fastening groove, and the first fastening hook is fastened to the first fastening groove.

4. The expansion card according to claim 1, wherein the fixing element has a second fastening hook and the second circuit board has a second fastening groove, and the second fastening hook is fastened to the second fastening groove.

5. An expansion card for installing at least one module to a main board, the expansion card comprising:
a first circuit board, for the module to be installed on, wherein the first circuit has at least one first mortise;
a second circuit board, inserted to the main board, wherein the second circuit board has at least one second mortise;
a flexible board, electrically connected to the first circuit board and the second circuit board;
a fixing element, fastened to a junction where the flexible board connects the first circuit board and the second circuit board, wherein the fixing element has a first fixing hole corresponding to the first mortise, and the fixing element has a second fixing hole that corresponds to the second mortise;
a first fastening element, fastened in the first mortise and the first fixing hole; and
a second fastening element, fastened in the second mortise and the second fixing hole.

6. The expansion card according to claim 5, wherein the first fastening element comprises a screw bolt, a rivet, a plastic stud or a tenon.

7. The expansion card according to claim 5, wherein the second fastening element comprises a screw bolt, a rivet, a plastic stud or a tenon.

8. A fixing structure for an expansion card used for installing at least one module to a main board, the fixing structure for the expansion card comprising:
a hard disk frame, disposed on the main board, wherein the hard disk frame has at least one compartment for carrying the module;
a first circuit board, disposed on the hard disk frame, for the module to be installed on;
a second circuit board, inserted to the main board;
a flexible board, electrically connected to the first circuit board and the second circuit board; and
a fixing element, fastened to a junction where the flexible board connects the first circuit board and the second circuit board.

9. The fixing structure for an expansion card according to claim 8, wherein the fixing element has a first plate, at least one reinforcing rib and a second plate, and the reinforcing rib is fastened to the first plate and the second plate.

10. The fixing structure for an expansion card according to claim 8, wherein the fixing element has a first fastening hook and the first circuit board has a first fastening groove, and the first fastening hook is fastened to the first fastening groove.

11. The fixing structure for an expansion card according to claim 8, wherein the fixing element has a second fastening hook and the second circuit board has a second fastening groove, and the second fastening hook is fastened to the second fastening groove.
